(19) United States
(12) Patent Application Publication
(10) Pub. No.: US 2024/0172549 A1
(43) Pub. Date: May 23, 2024

(54) DISPLAY DEVICE

(71) Applicant: Samsung Display Co., Ltd., Yongin-si (KR)

(72) Inventors: Jaiku Shin, Yongin-si (KR); Sungchul Choi, Yongin-si (KR); Sojeong La, Yongin-si (KR)

(21) Appl. No.: 18/509,042

(22) Filed: Nov. 14, 2023

(30) Foreign Application Priority Data
Nov. 18, 2022 (KR) 10-2022-0155793

(51) Int. Cl. H10K 77/10; H10K 59/40

(52) U.S. Cl. CPC H10K 77/111; H10K 59/40; H10K 2102/311

(57) ABSTRACT

A display device includes: a display panel including: a folding axis: and a folding area and non-folding areas on both sides of the folding axis, the display panel being configured to be folded along the folding axis, the folding area including a curvature area, inflection areas on both sides of the curvature area, and an extension area between the curvature area and the inflection areas; and a first plate below the display panel, wherein the first plate includes a lattice structure overlapping the curvature area, and is formed as a continuous plane throughout the extension area, the inflection areas, and the non-folding areas.

### CROSS-REFERENCE TO RELATED APPLICATION

The present application claims priority to and the benefit of Korean Patent Application No. 10-2022-0155793, filed on Nov. 18, 2022, in the Korean Intellectual Property Office, the entire disclosure of which is incorporated herein by reference.

### BACKGROUND

### 1. Field

Aspects of one or more embodiments relate to a display device.

### 2. Description of the Related Art

Recently, electronic devices have been widely used for various applications. The electronic devices, such as mobile electronic devices and fixed electronic devices, are variously used, and such electronic devices include display devices for display, to users, visual information, such as images or videos, so as to support various functions.

Recently, with the miniaturization of components for driving display devices, proportions of the display devices occupying the electronic devices are gradually increasing, and display devices having structures that are capable of being bent from flat states to have certain angles or to be folded along one or more folding axes are also being developed.

Foldable display devices may designed to be folded or unfolded along one or more folding axes without damaging the display device. In this case, structures enabling the display devices to be folded in dumbbell shapes may be considered.

The above information disclosed in this Background section is only for enhancement of understanding of the background and therefore the information discussed in this Background section does not necessarily constitute prior art.

### SUMMARY

Aspects of one or more embodiments relate to a display device, and for example, to a foldable display device.

Aspects of one or more embodiments include a display device, in which a display panel has a relatively uniform surface.

However, such characteristics are merely an example and characteristics according to the present disclosure are not limited thereto.

Additional aspects will be set forth in part in the description which follows and, in part, will be apparent from the description, or may be learned by practice of the presented embodiments of the disclosure.

According to one or more embodiments, a display device includes a display panel including a folding area and non-folding areas arranged on both sides of the folding area, and being folded in the folding area, the folding area including a curvature area, inflection areas arranged on both sides of the curvature area, and an extension area arranged between the curvature area and the inflection areas, and a first plate below the display panel, wherein the first plate includes a lattice structure overlapping the curvature area, and is provided as a continuous plane throughout the extension area, the inflection areas, and the non-folding areas.

According to some embodiments, a rigidity index may be defined by Equation 1, and a rigidity index of the first plate may be between 40 and 400.

S=T³·X·1000 Equation 1

where S may denote a rigidity index, T may denote a thickness of a plate in mm, and X may denote a modulus of a plate in MPa.

According to some embodiments, a thickness of the first plate may be in a range according to Equation 2.

2·10⁻⁶X1²−0.0009·X1+0.1364≤T1≤4·10⁻⁶X1²−0.0014·X1+0.2068 Equation 2

where T1 may denote a thickness of the first plate in mm and X1 may denote a modulus of the first plate in MPa.

According to some embodiments, the display device may further include a second plate below the first plate, wherein the second plate may be arranged to overlap at least a portion of the non-folding areas.

According to some embodiments, the second plate may not be arranged in the folding area.

According to some embodiments, a rigidity index may be defined by Equation 1, and a rigidity index of the second plate may be greater than 20.

S=T³·X·1000 Equation 1

where S may denote a rigidity index, T may denote a thickness of a plate in mm, and X may denote a modulus of a plate in MPa.

According to some embodiments, a thickness of the second plate may be in a range according to Equation 3.

8·10⁻⁷X2²−0.0004·X2+0.0874≤T2 Equation 3

where T2 may denote a thickness of the second plate in mm and X2 may denote a modulus of the second plate in MPa.

According to some embodiments, the first plate may include stainless steel and the second plate may include a copper alloy.

According to some embodiments, the first plate may include fiber reinforced plastic and the second plate may include stainless steel.

According to some embodiments, the non-folding areas may include a first non-folding area arranged at one side of the folding area and a second non-folding area arranged at the other side of the folding area, the second plate may include a (2-1)th plate overlapping the first non-folding area and a (2-2)th plate overlapping the second non-folding area, and the display device may further include a display circuit board overlapping the first non-folding area and the (2-1)th plate and below the (2-1)th plate.

According to some embodiments, the (2-1)th plate and the (2-2)th plate may include different materials.

According to some embodiments, a modulus of the (2-2)th plate may be smaller than a modulus of the (2-1)th plate.

According to some embodiments, a portion of the (2-1)th plate, which overlaps the display circuit board, and another portion of the (2-1)th plate, which does not overlap the display circuit board, may include different materials.

According to one or more embodiments, a display device includes a display panel including a folding area and non-folding areas arranged on both sides of the folding area, and being folded in the folding area, the folding area including a curvature area, inflection areas arranged on both sides of the curvature area, and an extension area arranged between the curvature area and the inflection areas, a first plate below the display panel, and a digitizer layer below the first plate, wherein the first plate includes a lattice structure overlapping the curvature area, and is provided as a continuous plane throughout the extension area, the inflection areas, and the non-folding areas.

According to some embodiments, a rigidity index may be defined by Equation 1, and a rigidity index of the first plate may be between 40 and 400.

S=T³·X·1000 Equation 1

where S may denote a rigidity index, T may denote a thickness of a plate in mm, and X may denote a modulus of a plate in MPa.

According to some embodiments, a thickness of the first plate may be in a range according to Equation 2.

2·10⁻⁶X1²−0.0009·X1+0.1364≤T1≤4·10⁻⁶X1²−0.0014·X1+0.2068 Equation 2

where, T1 may denote a thickness of the first plate in mm and X1 may denote a modulus of the first plate in MPa.

According to some embodiments, the display device may further include a second plate below the digitizer layer, wherein the second plate may be arranged to overlap at least a portion of the non-folding areas.

According to some embodiments, a rigidity index may be defined by Equation 1, and a rigidity index of the second plate may be greater than 20.

S=T³·X·1000 Equation 1

where S may denote a rigidity index, T may denote a thickness of a plate in mm, and X may denote a modulus of a plate in MPa.

According to some embodiments, a thickness of the second plate may be in a range according to Equation 3.

8·10⁻⁷X2²−0.0004·X2+0.0874≤T2 Equation 3

where T2 may denote a thickness of the second plate in mm and X2 may denote a modulus of the second plate in MPa.

According to some embodiments, the display device may further include a buffer layer arranged between the digitizer layer and the second plate.

Aspects, features, and characteristics other than those described above will become more apparent from the detailed descriptions, claims, and drawings for implementing the disclosure.

### BRIEF DESCRIPTION OF THE DRAWINGS

The above and other aspects, features, and characteristics of certain embodiments of the disclosure will be more apparent from the following description taken in conjunction with the accompanying drawings, in which:

FIGS. 1 and 2 are perspective views of a display device according to some embodiments;

FIG. 3 is a cross-sectional view of a portion of the display device taken along a line III-III′ of FIG. 1, according to some embodiments;

FIG. 4 is an enlarged cross-sectional view of a display panel of FIG. 3, according to some embodiments;

FIGS. 5 and 6 are cross-sectional views of a display device, according to some embodiments;

FIG. 7 is a graph of a thickness of a first plate with respect to a modulus of the first plate, according to some embodiments;

FIG. 8 is a graph of a thickness of a second plate with respect to a modulus of the second plate, according to some embodiments;

FIG. 9 is a cross-sectional view of a display device according to some embodiments;

FIGS. 10 through 12 are cross-sectional views of a display device, according to some embodiments; and

FIGS. 13 and 14 are cross-sectional views of a display device, according to some embodiments.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may have various modifications and various embodiments, and specific embodiments are illustrated in the drawings and are described in more detail in the detailed description. Effects and features of the disclosure and methods of achieving the same will become apparent with reference to embodiments described in more detail with reference to the drawings. However, the disclosure is not limited to the embodiments described below, and may be implemented in various forms.

Hereinafter, aspects of some embodiments will be described in more detail with reference to the accompanying drawings, and in the following description with reference to the drawings, like reference numerals refer to like elements and redundant descriptions thereof will be omitted.

In the following embodiments, the terms “first” and “second” are not used in a limited sense and are used to distinguish one component from another component.

In the following embodiments, an expression used in the singular encompasses the expression of the plural, unless it has a clearly different meaning in the context.

In the following embodiments, it will be further understood that the terms “comprise” and/or “comprising” used herein specify the presence of stated features or components, but do not preclude the presence or addition of one or more other features or components.

It will be understood that when a layer, region, or element is referred to as being “formed on” another layer, area, or element, it can be directly or indirectly formed on the other layer, region, or element. That is, for example, intervening layers, regions, or elements may be present.

In the drawings, for convenience of description, sizes of components may be exaggerated or reduced. In other words, because sizes and thicknesses of components in the drawings are arbitrarily illustrated for convenience of explanation, the disclosure is not necessarily limited thereto.

According to some embodiments, an x-axis, a y-axis, and a z-axis are not limited to three axes on an orthogonal coordinate system, but may be interpreted in a broad sense including the three axes. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

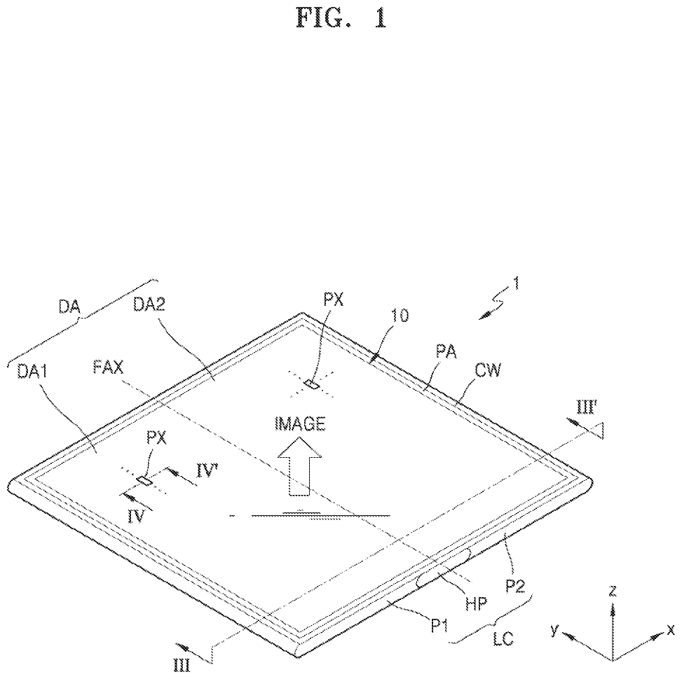

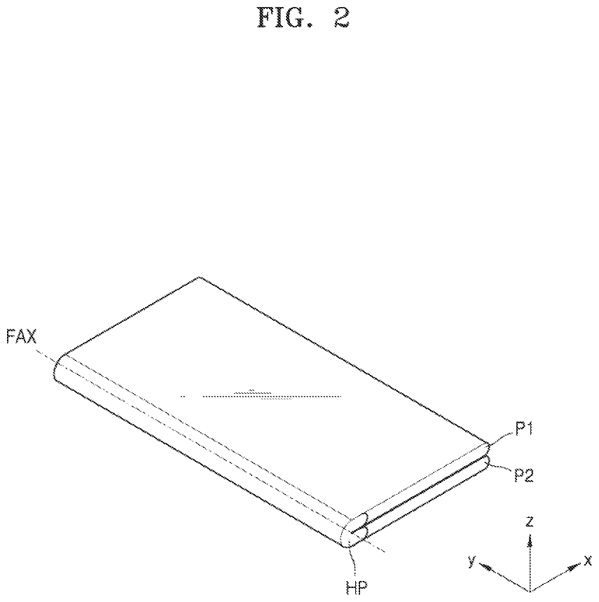

FIGS. 1 and 2 are perspective views of a display device 1 according to some embodiments. For example, FIG. 1 illustrates the display device 1 in an unfolded state, and FIG. 2 illustrates the display device 1 in a folded state.

Referring to FIGS. 1 through 2, the display device 1 is a device configured to display moving images or still images, and may be used as a display screen of not only portable electronic devices, such as a mobile phone, a smart phone, a tablet personal computer (PC), a mobile communication terminal, an electronic notebook, an electronic book, a portable multimedia player (PMP), a navigation device, and an ultra mobile PC (UMPC), but also various products, such as a television, a laptop computer, a monitor, a billboard, and Internet of things (IoT) device. Also, the display device 1 according to some embodiments may be used for wearable devices, such as a smart watch, a watch phone, a glasses-type display, and a head mounted display (HMD). In addition, the display device 1 according to some embodiments may be used as a panel of a vehicle, a center information display (CID) arranged on a center fascia or dashboard of a vehicle, a room mirror display replacing a side mirror of a vehicle, or a display arranged on a rear surface of a front seat, as entertainment for a back seat of a vehicle.

As shown in FIG. 1, the display device 1 may have an approximately rectangular shape. For example, as shown in FIG. 1, the display device 1 may have a rectangular plane shape in overall, having short sides extending in a first direction (for example, an x direction or −x direction) and long sides extending in a second direction (for example, a y direction or −y direction). According to some embodiments, a portion where the short side extending in the first direction (for example, the x direction or −x direction) and the long side extending in the second direction (for example, the y direction or −y direction) meet may have right-angled shape or a round shape having certain curvature. Obviously, the plane shape of the display device 1 is not limited to a rectangle, and may be another polygon, a circle, or an oval.

The display device 1 may include a lower cover LC, a display panel 10, and a cover window CW.

The lower cover LC may form a bottom exterior of the display device 1. The lower cover LC may include plastic, a metal, or both plastic and a metal. The lower cover LC may include a first portion P1 and a second portion P2, which support the display panel 10. The lower cover LC may be folded based on a folding axis FAX defined between the first portion P1 and the second portion P2. According to some embodiments, the lower cover LC may further include a hinge portion HP, and the hinge portion HP may be located between the first portion P1 and the second portion P2.

The display panel 10 may include a display area DA and a peripheral area PA. The display area DA may display images. According to some embodiments, pixels PX may be arranged in the display area DA. The display panel 10 may display images by using light emitted from the pixels PX. Each of the pixels PX may emit light by using a display element. According to some embodiments, each of the pixels PX may emit red, green, or blue light. According to some embodiments, each of the pixels PX may emit red, green, blue, or white light.

The peripheral area PA may an area that does not provide an image and may be a non-display area. The peripheral area PA may surround at least a portion of the display area DA. For example, the peripheral area PA may entirely surround the display area DA. A driving unit for providing an electric signal to the pixels PX, or a power supply wire for providing power may be arranged in the peripheral area PA. For example, a scan driving unit for applying a scan signal to the pixels PX may be arranged in the peripheral area PA. Also, a data driving unit for applying a data signal to the pixels PX may be arranged in the peripheral area PA.

The display area DA may include a first display area DA1 and a second display area DA2 provided on both sides based on the folding axis FAX crossing the display area DA. The first display area DA1 and the second display area DA2 may be arranged on the first portion P1 and the second portion P2 of the lower cover LC, respectively. The display panel 10 may provide a first image and a second image by using light emitted from the plurality of pixels PX arranged in the first display area DA1 and the second display area DA2. According to some embodiments, the first image and the second image may be portions of an image displayed at the display area DA of the display panel 10. Alternatively, according to some embodiments, the display panel 10 may display a first image and a second image, which are independent from each other.

The display panel 10 may be folded based on the folding axis FAX. According to some embodiments, when the display panel 10 is folded, the first display area DA1 and the second display area DA2 of the display panel 10 may face each other. According to some embodiments, when the display panel 10 is folded, the first display area DA1 and the second display area DA2 of the display panel 10 may face opposite directions.

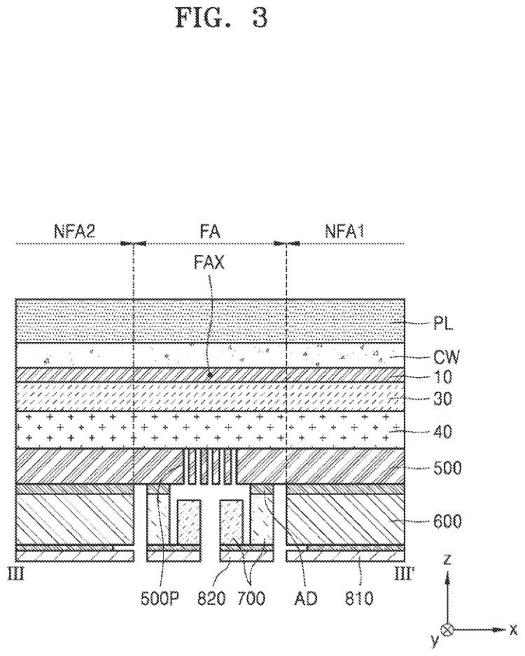

In other words, according to some embodiments, the display panel 10 may be in-folded or out-folded based on the folding axis FAX. According to some embodiments, in-folding may indicate that the display panel 10 is folded in a +z direction, based on the folding axis FAX, and out-folding may indicate that the display panel 10 is folded in a −z direction, based on the folding axis FAX. In other words, the in-folding may indicate that the display panel 10 is folded such that top surfaces of the cover window CW located on the display panel 10 face each other, and the out-folding may indicate that the display panel 10 is folded such that bottom surfaces of the cover window CW face each other. According to some embodiments, the bottom surface of the cover window CW may be a surface closer to a substrate 100 of FIG. 3 than the top surface of the cover window CW, in a z direction.

In FIGS. 1 and 2, the folding axis FAX extends in the second direction (the y direction), but embodiments according to the present disclosure are not limited thereto. According to some embodiments, the folding axis FAX may extend in the first direction (the x direction) crossing the second direction (the y direction). Alternatively, the folding axis FAX may extend in a direction crossing the first direction (the x direction) and the second direction (the y direction), on a xy plane.

In FIGS. 1 and 2, there is on folding axis FAX, but the disclosure is not limited thereto. According to some embodiments, the display panel 10 may be folded based on two folding axes FAX crossing the display area DA. For example, when the display panel 10 is folded based on the two folding axes FAX, the display panel 10 may be in-folded based on one folding axis FAX and out-folded based on the other folding axis FAX. Alternatively, the display panel 10 may be in-folded or out-folded based on both the two folding axes FAX. According to some embodiments, the display panel 10 may be folded based on a plurality of folding axes FAX crossing the display area DA. According to some embodiments, the display panel 10 may be in-folded or out-folded based on each of the folding axes FAX.

The cover window CW may be located on the display panel 10 and cover the display panel 10. The cover window CW may be folded or curved according to external force, without causing a crack or the like. When the display panel 10 is folded based on the folding axis FAX, the cover window CW may also be folded and cover the display panel 10.

FIG. 3 is a cross-sectional view of a portion of the display device 1, according to some embodiments. FIG. 3 may correspond to a cross section taken along a line III-III′ of FIG. 1.

Referring to FIG. 3, the display device 1 may include the display panel 10, the cover window CW, a protection layer PL, a protection film 30, a cover panel 40, a first plate 500, and a second plate 600.

The display panel 10 may display information processed by the display device 1. For example, the display panel 10 may display execution screen information of an application driven by the display device 1, or user interface (UI) or graphics user interface (GUI) information according to the execution screen information.

The display panel 10 may include the display element. For example, the display panel 10 may be an organic light-emitting display panel using an organic light-emitting diode, a micro-LED display panel using a micro-LED, a quantum dot light-emitting display panel using a quantum dot LED including a quantum dot emission layer, or an inorganic light-emitting display panel using an inorganic LED including an organic semiconductor. Hereinafter, embodiments in which the display panel 10 is an organic light-emitting display panel using an organic light-emitting diode as a display element will be described in more detail.

The cover window CW may be located on the display panel 10. The cover window CW may protect the display panel 10. According to some embodiments, the cover window CW may be a flexible window. The cover window CW may protect the display panel 10 by being easily bent according to external force without causing a crack or the like. The cover window CW may include at least one of glass, sapphire, or plastic. The cover window CW may be, for example, ultra-thin glass (UTG) or colorless polyimide (CPI).

The cover window CW may be adhered to the display panel 10 by an adhesive member. The adhesive member may be a pressure sensitive adhesive (PSA). The adhesive member may be a transparent adhesive member, such as an optically clear adhesive (OCA) film. Such an adhesive member may be formed on a top portion of the display panel 10 via various methods, for example, formed in the form of a film and adhered to the top portion of the display panel 10 (for example, a top portion of an encapsulation layer) or formed in the form of a material and coated on the top portion of the display panel 10.

The protection layer PL may be located on the cover window CW. The protection layer PL may be arranged to cover one surface of the cover window CW to protect the cover window CW. Accordingly, rigidity of the cover window CW may be reinforced.

According to some embodiments, an optical functional layer and a touch sensor layer may be located between the display panel 10 and the cover window CW. For example, the touch sensor layer may be located on the display panel 10. The touch sensor layer may obtain coordinate information according to an external input, for example, a touch event.

According to some embodiments, the optical functional layer may be located on the touch sensor layer. The optical functional layer may reduce reflectance of light (external light) incident from the outside towards a display device, and/or enhance color purity of light emitted from the display device. According to some embodiments, the optical functional layer may include a retarder and/or a polarizer. The retarder may be a film type or liquid crystal coating type, and may include a λ/2 retarder and/or a λ/4 retarder. The polarizer may also be a film type or a liquid crystal coating type. The film type may include an elongated synthetic resin film, and the liquid crystal coating type may include liquid crystals arranged in a certain arrangement. The retarder and the polarizer may further include a protection film.

The protection film 30 may be located below the display panel 10. The protection film 30 may be adhered to the bottom of the display panel 10 through an adhesive member. The protection film 30 may be adhered to the bottom of the display panel 10 to support and protect the display panel 10. The protection film 30 may include polyethylene terephthalate (PET) or polyimide (PI). The protection film 30 may be adhered in the form of a film, but is not limited thereto and may be stacked and arranged in another form.

The cover panel 40 may be located below the protection film 30. According to some embodiments, the cover panel 40 may support the display panel 10 and the protection film 30. According to some embodiments, the cover panel 40 may include a polymer material.

The first plate 500 may be located below the cover panel 40. The first plate 500 may support the display panel 10. Accordingly, a degree of a center portion of the display panel 10 being sagged in the −z direction due to its weight is reduced, and thus the display panel 10 is not easily damaged even when an external impact is applied. According to some embodiments, the first plate 500 may include a folding pattern 500P. The folding pattern 500P may be arranged in a folding area FA and change a shape or length when the display device 1 is folded. Accordingly, the folding pattern 500P may be provided such that the folding pattern 500P is folded based on the folding axis FAX when the display device 1 is folded, and is symmetrical based on the folding axis FAX.

The second plate 600 may be arranged below the first plate 500. The second plate 600 may protect the display device 1 from an external impact, together with the first plate 500. Also, the second plate 600 may prevent various members, such as the driving unit, arranged below the display panel 10, from being visible.

According to some embodiments, the second plate 600 may overlap a non-folding area NFA. According to some embodiments, a sag preventing member 700 may be arranged on a same layer as the second plate 600 to overlap the folding area FA. In other words, two second plates 600 may be spaced apart from each other with the folding area FA therebetween, and the sag preventing member 700 may be arranged between the two second plates 600. A portion of the sag preventing member 700 may be adhered to the first plate 500 by an adhesive member AD, thereby preventing or reducing sagging of the first plate 500, for example, the first plate 500 in the folding area FA.

A flat plate 810 may be arranged below the second plate 600. Also, a wing plate 820 may be arranged below the sag preventing member 700.

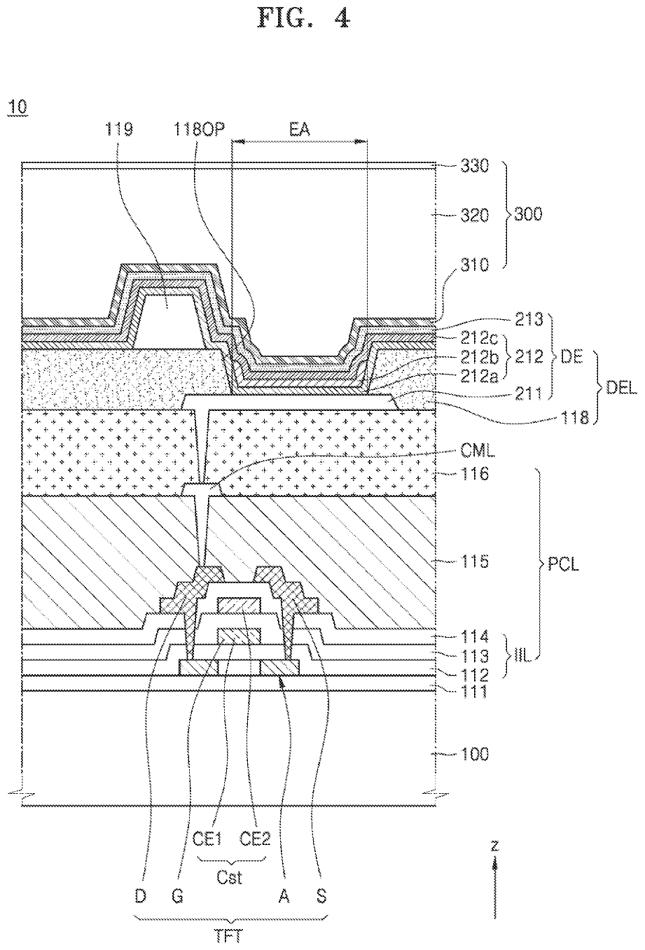

FIG. 4 is a cross-sectional view of the display panel 10 taken along a line IV-IV″ of FIG. 1, according to some embodiments.

Referring to FIG. 4, the display panel 10 may include the substrate 100, a buffer layer 111, a pixel circuit layer PCL, a display element layer DEL, and an encapsulation layer 300.

The substrate 100 may be glass or include a polymer resin, such as polyether sulfone, polyarylate, polyetherimide, polyethylene naphthalate, polyethylene terephthalate, polyphenylene sulfide, polyimide, polycarbonate, cellulose triacetate, or cellulose acetate propionate. According to some embodiments, the substrate 100 may have a multilayer structure including a base layer including the polymer resin and a barrier layer. The substrate 100 including the polymer resin may have a flexible, rollable, or bendable characteristic.

The buffer layer 111 may be located on the substrate 100. The buffer layer 111 may include an inorganic insulating material, such as silicon nitride, silicon oxynitride, or silicon oxide, and may be a single layer or multilayer including the above inorganic insulating material.

The pixel circuit layer PCL may be arranged on the buffer layer 111. The pixel circuit layer PCL may include a thin-film transistor TFT included in a pixel circuit, and an inorganic insulating layer IIL, a first planarization layer 115, and a second planarization layer 116, which are arranged below and/or on components of the thin-film transistor TFT. The inorganic insulating layer IIL may include a first gate insulating layer 112, a second gate insulating layer 113, and an interlayer insulating layer 114.

The thin-film transistor TFT includes a semiconductor layer A, and the semiconductor layer A may include polysilicon. Alternatively, the semiconductor layer A may include amorphous silicon, an oxide semiconductor, or an organic semiconductor. The semiconductor layer A may include a channel region, and a drain region and a source region, which are arranged on both sides of the channel region respectively. A gate electrode G may overlap the channel region.

The gate electrode G may include a low-resistance metal material. The gate electrode G may include a conductive material including molybdenum (Mo), aluminum (Al), copper (Cu), or titanium (Ti), and may be formed in a multilayer or single layer including the conductive material.

The first gate insulating layer 112 between the semiconductor layer A and the gate electrode G may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). ZnO_{X} may be ZnO and/or ZnO₂.

The second gate insulating layer 113 may be provided to cover the gate electrode G. Like the first gate insulating layer 112, the second gate insulating layer 113 may include an inorganic insulating material, such as SiO₂, SiNₓ, SiON, Al₂O₃, TiO₂, Ta₂O₅, HfO₂, and/or ZnOₓ. ZnO_{X} may be ZnO and/or ZnO₂.

An upper electrode CE2 of a storage capacitor Cst may be arranged on the second gate insulating layer 113. The upper electrode CE2 may overlap the gate electrode G therebelow. According to some embodiments, the upper electrode CE2 and the gate electrode G, which overlap with the second gate insulating layer 113 therebetween, may form the storage capacitor Cst of the pixel circuit. In other words, the gate electrode G may operate as a lower electrode CE1 of the storage capacitor Cst. As such, the storage capacitor Cst and the thin-film transistor TFT may overlap each other. According to some embodiments, the storage capacitor Cst may not overlap the thin-film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multilayer including such a material.

The interlayer insulating layer 114 may cover the upper electrode CE2. The interlayer insulating layer 114 may include SiO₂, SiNₓ, SiON, Al₂O₃, TiO₂, Ta₂O₅, HfO₂, or ZnOₓ. ZnO_{X} may be ZnO and/or ZnO₂. The interlayer insulating layer 114 may be a single layer or multilayer including the inorganic insulating material described above.

A drain electrode D and a source electrode S may each be located on the interlayer insulating layer 114. The drain electrode D and the source electrode S may include a material having relatively good conductivity. The drain electrode D and the source electrode S may include a conductive material including Mo, Al, Cu, or Ti, and may be formed in a multilayer or single layer including the conductive material. According to some embodiments, the drain electrode D and the source electrode S may have a multilayer structure of Ti/Al/Ti.

The first planarization layer 115 may cover the drain electrode D and the source electrode S. The first planarization layer 115 may include an organic insulating layer. The first planarization layer 115 may include an organic insulating material, such as a general-purpose polymer, for example, polymethylmethacrylate (PMMA) or polystyrene (PS), a polymer derivate having a phenol-based group, an acrylic-based polymer, an imide-based polymer, an arylether-based polymer, an amide-based polymer, a fluorine-based polymer, a p-xylene-based polymer, a vinyl alcohol-based polymer, or a blend thereof.

A connection electrode CML may be arranged on the first planarization layer 115. According to some embodiments, the connection electrode CML may be connected to the drain electrode D or source electrode S through a contact hole of the first planarization layer 115. The connection electrode CML may include a material having good conductivity. The connection electrode CML may include a conductive material including Mo, Al, Cu, or Ti, and may be formed in a multilayer or single layer including the conductive material. According to some embodiments, the connection electrode CML may have a multilayer structure of Ti/Al/Ti.

The second planarization layer 116 may cover the connection electrode CML. The second planarization layer 116 may include an organic insulating material. The second planarization layer 116 may include an organic insulating material, such as a general-purpose polymer, for example, PMMA or PS, a polymer derivate having a phenol-based group, an acrylic-based polymer, an imide-based polymer, an arylether-based polymer, an amide-based polymer, a fluorine-based polymer, a p-xylene-based polymer, a vinyl alcohol-based polymer, or a blend thereof.

The display element layer DEL may be arranged on the pixel circuit layer PCL. The display element layer DEL may include a display element DE. The display element DE may be an organic light-emitting diode (OLED). A pixel electrode 211 of the display element DE may be electrically connected to the connection electrode CML through a contact hole of the second planarization layer 116.

The pixel electrode 211 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to some embodiments, the pixel electrode 211 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. According to some embodiments, the pixel electrode 211 may further include a film including ITO, IZO, ZnO, or In₂O₃ on/below the reflective layer.

A pixel-defining layer 118 having an opening 118OP exposing a center portion of the pixel electrode 211 may be arranged on the pixel electrode 211. The pixel-defining layer 118 may include an organic insulating material and/or an inorganic insulating material. The opening 1180P may define an emission area EA of light emitted from the display element DE. For example, a width of the opening 118OP may correspond to a width of the emission area EA of the display element DE.

According to some embodiments, the pixel-defining layer 118 may include a light-blocking material and may be provided in black. The light-blocking material may include a resin or paste including carbon black, carbon nanotubes, or black dyes, metal particles such as nickel, aluminum, molybdenum, and an alloy thereof, metal oxide particles (for example, chromium oxide), or metal nitride particles (for example, chromium nitride). When the pixel-defining layer 118 includes the light-blocking material, external light reflection caused by metal structures arranged below the pixel-defining layer 118 may be reduced.

A spacer 119 may be arranged on the pixel-defining layer 118. The spacer 119 may be used to prevent a damage to the substrate 100 in a method of manufacturing the display device 1. A mask sheet may be used while manufacturing the display panel 10, and at this time, the spacer 119 may prevent the mask sheet from entering into the opening 118OP of the pixel-defining layer 118 or prevent a part of the substrate 100 from being damaged or broken by the mask sheet while depositing a deposition material on the substrate 100 close to the pixel-defining layer 118.

The spacer 119 may include an organic insulating material, such as polyimide. Alternatively, the spacer 119 may include an inorganic insulating material, such as silicon nitride or silicon oxide, or may include an organic insulating material and an inorganic insulating material.

According to some embodiments, the spacer 119 may include a material different from the pixel-defining layer 118. According to some embodiments, the spacer 119 may include a same material as the pixel-defining layer 118 and in this case, the pixel-defining layer 118 and the spacer 119 may be formed together during a mask process using a half-tone mask or the like.

An intermediate layer 212 may be arranged on the pixel-defining layer 118. The intermediate layer 212 may include an emission layer 212b arranged at the opening 1180P of the pixel-defining layer 118. The emission layer 212b may include a high-molecular weight organic material or low-molecular weight organic material, which emit light of certain color.

A first functional layer 212a and a second functional layer 212c may be respectively arranged below and on the emission layer 212b. The first functional layer 212a may include, for example, a hole transport layer (HTL) or may include an HTL and a hole injection layer (HIL). The second functional layer 212c is a component arranged on the emission layer 212b and may be optional. The second functional layer 212c may include an electron transport layer (ETL) and/or an electron injection layer (EIL). Like an opposing electrode 213 described below, the first functional layer 212a and/or the second functional layer 212c may be a common layer formed to entirely cover the substrate 100.

The opposing electrode 213 may include a conductive material with a low work function. For example, the opposing electrode 213 may include a (semi-)transparent layer including Ag, Mg, Al, Pt, Pd, Au, Ni, Nd, Ir, Cr, lithium (Li), calcium (Ca), or an alloy thereof. Alternatively, the opposing electrode 213 may further include a layer including ITO, IZO, ZnO, or In₂O₃, on the (semi-)transparent layer including the above material.

According to some embodiments, a capping layer may be further arranged on the opposing electrode 213. The capping layer may include lithium fluoride (LiF), an inorganic material, and/or an organic material.

The encapsulation layer 300 may be arranged on the opposing electrode 213. According to some embodiments, the encapsulation layer 300 includes at least one inorganic encapsulation layer and at least one organic encapsulation layer, and FIG. 4 shows that the encapsulation layer 300 includes a first inorganic encapsulation layer 310, an organic encapsulation layer 320, and a second inorganic encapsulation layer 330, which are sequentially stacked.

The first inorganic encapsulation layer 310 and second inorganic encapsulation layer 330 may include one or more inorganic materials from among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include an acrylic resin, an epoxy resin, polyimide, and polyethylene. According to some embodiments, the organic encapsulation layer 320 may include acrylate.

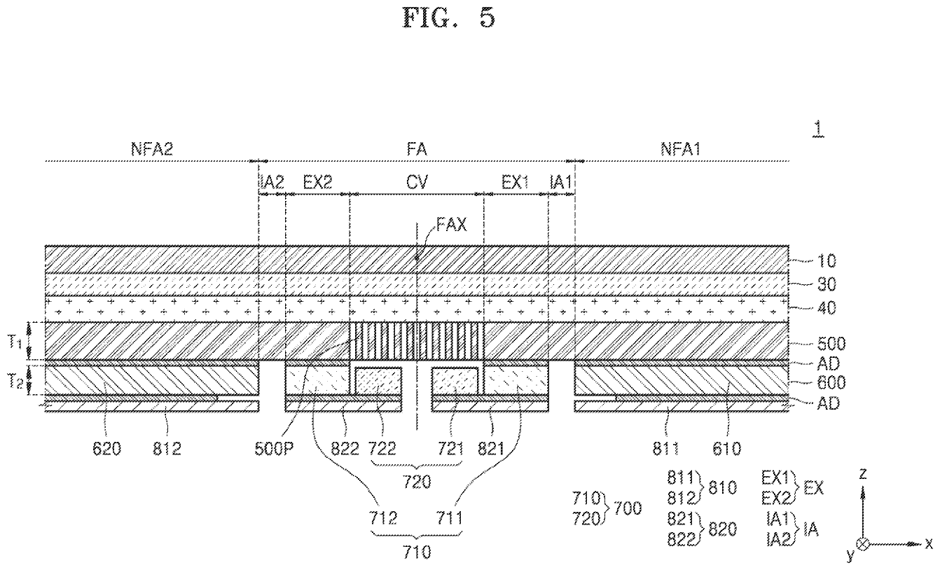

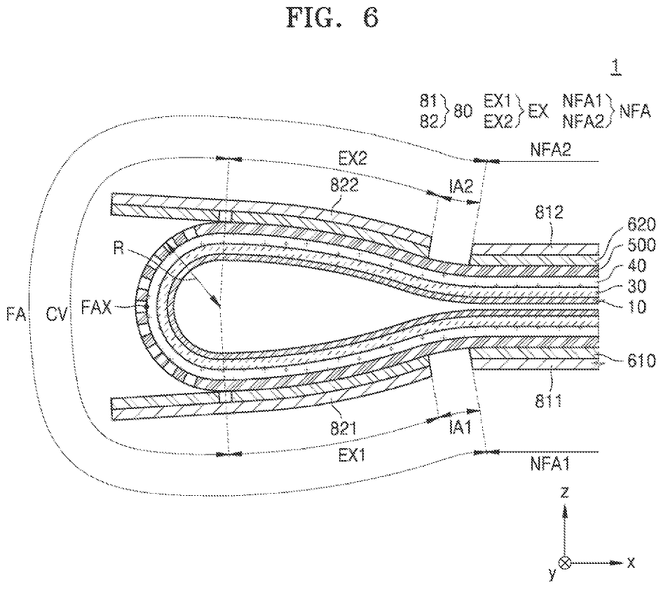

FIGS. 5 and 6 are cross-sectional views of the display device 1, according to some embodiments. FIGS. 5 and 6 are views showing the display device 1 of FIG. 3 in more detail, wherein FIG. 5 shows the display device 1 in an unfolded state and FIG. 6 shows the display device 1 in a folded state.

Referring to FIG. 5, the display device 1 may include the folding area FA and the non-folding areas NFA. The folding area FA and the non-folding areas NFA may be areas defined by also extending in a thickness direction (for example, the z direction of FIG. 5) of the display device 1. In other words, the display panel 10 may also include the folding area FA and the non-folding areas NFA.

The folding area FA may be an area including the folding axis FAX and folded with certain curvature, based on the folding axis FAX. According to some embodiments, the folding area FA may include a curvature area CV that substantially forms a portion of a circular arc by being bent to have the certain curvature. Also, the folding area FA may include extension areas EX extending from both end portions of the curvature area CV, for example, a first extension area EX1 connected to one end portion of the curvature area CV and a second extension area EX2 connected to the other end portion of the curvature area CV. The extension areas EX may include curved surfaces continuous to the curvature of the curvature area CV, and as shown in FIG. 6, the first extension area EX1 and the second extension area EX2 may be arranged to face each other when the display device 1 is folded.

The non-folding areas NFA may be connected to both end portions of the folding area FA. The non-folding areas NFA may be areas that are not substantially folded, i.e., that are substantially plane. The non-folding areas NFA being substantially plane may indicate that the non-folding areas NFA are plane except for portions of the non-folding areas NFA adjacent to the folding area FA. The non-folding areas NFA may include a first non-folding area NFA1 connected to a side of the first extension area EX1 and a second non-folding area NFA2 connected to a side of the second extension area EX2, and as shown in FIG. 6, the first non-folding area NFA1 and the second non-folding area NFA2 may be arranged to face each other when the display device 1 is folded.

As shown in FIG. 6, the display panel 10 may be folded in a dumbbell shape. According to some embodiments, the display panel 10 may bend to have certain curvature at the curvature area CV. The first extension area EX1 and the second extension area EX2 may extend to be closer to each other while facing each other, towards a direction away from the curvature area CV. The first non-folding area NFA1 and the second non-folding area NFA2 may be substantially parallel to each other while facing each other. Thus, a shape of the display panel 10 when folded may be similar to a dumbbell shape.

Meanwhile, the folding area FA and the non-folding areas NFA may overlap the display area DA of FIG. 1. For example, the folding area FA may overlap portions of the first display area DA1 and second display area DA2. Also, the first non-folding area NFA1 may overlap a portion of the first display area DA1 and the second non-folding area NFA2 may overlap a portion of the second display area DA2.

The folding area FA may further include inflection areas IA. The inflection areas IA may be arranged at both end portions of the folding area FA in the first direction (for example, the x direction of FIG. 5). The inflection area IA may be arranged between the extension area EX and the non-folding area NFA. According to some embodiments, the inflection areas IA may include a first inflection area IA1 provided between the first extension area EX1 and the first non-folding area NFA1, and a second inflection area IA2 provided between the second extension area EX2 and the second non-folding area NFA2. The first inflection area IA1 and the second inflection area IA2 are similar, and thus the first inflection area IA1 will be mainly described below.

The first inflection area IA1 may be a reverse curvature portion in which a direction of curvature is reversed when the display device 1 is folded. According to some embodiments, the first inflection area IA1 may denote an area in which a direction of a curved surface of the display device 1, in particular, the display panel 10, is changed when the display device 1 is folded in the dumbbell shape. In other words, the display panel 10 may start to bend concavely in the folding area FA, in particular, the curvature area CV and the first extension area EX1, and convexly in the first inflection area IA1.

As described above, the protection film 30 and the cover panel 40 may be provided below the display panel 10. Also, the first plate 500 and the second plate 600 may be provided below the cover panel 40.

According to some embodiments, the first plate 500 may include the folding pattern 500P, for example, a lattice structure, provided to overlap the folding area FA, in particular, the curvature area CV. The lattice structure may include a plurality of openings that are spaced apart from each other in the first direction (for example, the x direction of FIG. 5) and extend in the second direction (for example, the y direction of FIG. 5) crossing the first direction, for example, in an extending direction of the folding axis FAX. Accordingly, the display device 1 may be further easily folded in the folding area FA.

According to some embodiments, the first plate 500 may not include an opening in the inflection areas IA that is the reverse curvature portion in which the direction of curvature is reversed during folding. In other words, the first plate 500 may be provided as a continuous plane throughout the extension areas EX, the inflection areas IA, and the non-folding areas NFA. As such, because an opening and/or a half-etched half opening is not arranged in the inflection area IA, generation of a flexure on the display panel 10 and such flexure being visible due to the opening and/or the half opening may be prevented or reduced.

According to some embodiments, the first plate 500 may have a small thickness for the inflection areas IA to be easily bent. A rigidity index is an index defined by a relationship between a thickness of a plate and a modulus of the plate, and may be defined as Equation 1 below.

S=T³·X·1000 Equation 1

where, S denotes a rigidity index of a plate, T denotes a thickness (mm) of the plate, and X denote a modulus (MPa) of the plate.

According to some embodiments, the first plate 500 may have a thickness T1 that makes a rigidity index to be smaller than 400. For example, when the first plate 500 is stainless steel having a modulus of 130 MPa, the thickness T1 of the first plate 500 may be smaller than 0.145 mm according to Equation 1.

When the rigidity index of the first plate 500 is greater than 400, the first plate 500 is not easily bent in the inflection area IA, and thus the curvature area CV forms very small curvature, for example, curvature smaller than 3 mm. Accordingly, the dumbbell may not be easily realized during folding.

Also, according to some embodiments, the first plate 500 may have the thickness T1 that makes the rigidity index to be greater than 40. For example, when the first plate 500 is stainless steel having the modulus of 130 MPa, the thickness T1 of the first plate 500 may be greater than 0.068 mm according to Equation 1.

When the rigidity index of the first plate 500 is smaller than 40, rigidity of the first plate 500 is low and thus the first plate 500 may be easily bent, but minimum rigidity to protect the display panel 10 and/or prevent or reduce damage to the folding pattern 500P may not be provided. Also, a foreign object may be visible when the foreign object penetrates into an upper or lower portion of the first plate 500.

In other words, the rigidity index of the first plate 500 may be greater than 40 and smaller than 400. This may be represented as formula below.

40<T1³·X1·1000<400

where T1 denotes a thickness (mm) of a first plate and X1 denotes a modulus (MPa) of the first plate.

For example, when the first plate 500 is stainless steel having a modulus of 130 MPa, the thickness T1 of the first plate 500 may be greater than 0.068 mm and smaller than 0.145 mm. The first plate 500 having such a rigidity index may easily realize the dumbbell shape during folding while protecting the display panel 10 and preventing or reducing visibility of the foreign object from the outside when the foreign object penetrates thereinto.

Table 1 below shows an example of a range of the thickness T1 of the first plate 500, which makes the rigidity index to be greater than 40 and smaller than 400, in different moduli of the first plate 500. According to some embodiments, the first plate 500 may include at least one of stainless steel, titanium alloy, aluminum, or fiber reinforced plastic.

TABLE 1

| | Modulus | Rigidity | Thickness Range |
|---|---|---|---|
| | (MPa) | Index | (mm) |
| Stainless | 130 | 40 to 400 | 0.068 to 0.145 |
| Steel | 170 | 40 to 400 | 0.062 to 0.132 |
| | 210 | 40 to 400 | 0.058 to 0.123 |
| Titanium | 90 | 40 to 400 | 0.077 to 0.164 |
| Alloy | 110 | 40 to 400 | 0.072 to 0.152 |
| Aluminum | 65 | 40 to 400 | 0.086 to 0.18 |
| | 75 | 40 to 400 | 0.082 to 0.17 |
| Fiber | 20 | 40 to 400 | 0.126 to 0.27 |
| Reinforced | 40 | 40 to 400 | 0.1 to 0.215 |
| Plastic | | | |

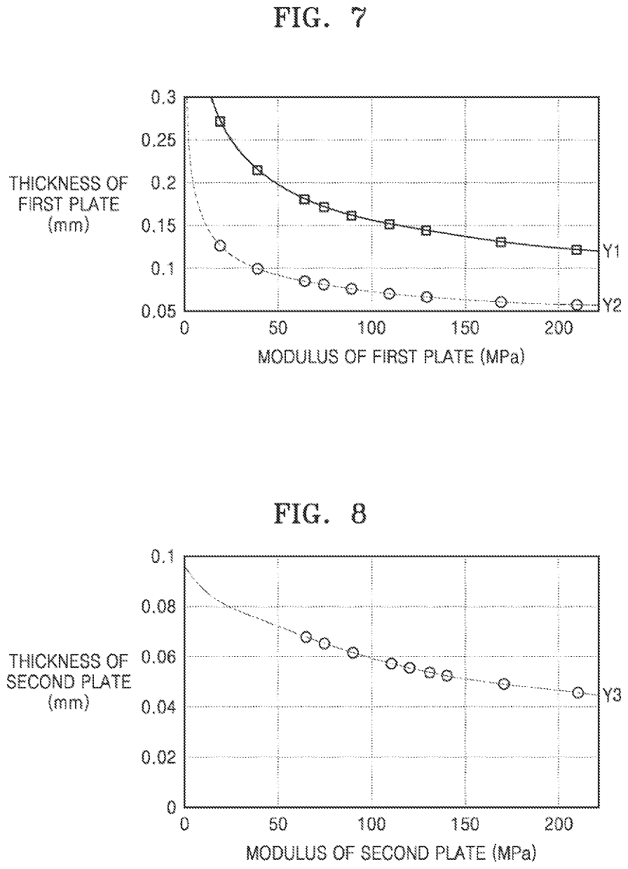

FIG. 7 is a graph of the thickness T1 of the first plate 500 with respect to the modulus of the first plate 500, according to some embodiments.

Referring to FIG. 7, the range of the thickness T1 of the first plate 500 with respect to the modulus of the first plate 500, which makes the rigidity index of the first plate 500 to be greater than 40 and smaller than 400, as in Table 1, may be represented as a graph.

In FIG. 7, each of dots in squares may correspond to a maximum value of the range of the thickness T1 of the first plate 500 with respect to each modulus in Table 1. Also, a trend line passing the dots in squares may be generated, and a corresponding curve Y1 may be represented as below.

Y1=4·10⁻⁶X1²−0.0014·X1+0.2068

where, X1 denotes a modulus (MPa) of a first plate.

Also, in FIG. 7, each of dots in circles may correspond to a minimum value of the range of the thickness T1 of the first plate 500 with respect to each modulus in Table 1. A trend line passing the dots in circles may be generated, and a corresponding curve Y2 may be represented as below.

Y2=2·10⁻⁶X1²−0.0009·X1+0.1364

where, X1 denotes a modulus (MPa) of a first plate.

As described above, the thickness T1 of the first plate 500 may have a value between Y1 and Y2. In other words, Y2≤T1≤Y1, and this may be represented as Equation 2 below.

2·10⁻⁶X1²−0.0009·X1+0.1364≤T1≤4·10⁻⁶X1²−0.0014·X1+0.2068 Equation 2

where, T1 denotes a thickness (mm) of a first plate and X1 denotes a modulus (MPa) of the first plate.

Referring back to FIGS. 5 and 6, the second plate 600 may be arranged below the first plate 500. According to some embodiments, the second plate 600 may be arranged to overlap at least a portion of the non-folding areas NFA, for example, at least portions of the first non-folding area NFA1 and second non-folding area NFA2. According to some embodiments, the second plate 600 may not be arranged in the folding area FA. In other words, the second plate 600 may be spaced apart from each other on both sides based on the folding area FA. The second plate 600 may reinforce the rigidity of the first plate 500. The second plate 600 has a reasonable thickness such that a flexure generated due to arrangement of other components, such as a display circuit board, which may be arranged below the second plate 600, is not visible from the outside.

In this regard, according to some embodiments, the second plate 600 may have a thickness T2 that makes a rigidity index to be greater than 20. For example, when the second plate 600 is stainless steel having the modulus of 130 MPa, the thickness T2 of the second plate 600 may be greater than 0.054 mm according to Equation 1 above.

When the rigidity index of the second plate 600 is smaller than 20, it may not be easy for the second plate 600 to reinforce the rigidity of the thin first plate 500. Also, the flexure generated due to the arrangement of the other components that may be arranged below the second plate 600 may be easily viewed.

This may be represented as formula below.

20<T2³·X2·1000

where, T2 denotes a thickness (mm) of a second plate and X2 denotes a modulus (MPa) of the second plate.

Table 2 below shows an example of a range of the thickness T2 of the second plate 600, which makes the rigidity index to be greater than 20, in different moduli of the second plate 600. According to some embodiments, the second plate 600 may include at least one of stainless steel, titanium alloy, aluminum, or copper alloy.

TABLE 2

| | Modulus | | Thickness Range |
|---|---|---|---|
| | (MPa) | Rigidity Index | (mm) |
| Stainless | 130 | 20~ | 0.054~ |
| Steel | 170 | 20~ | 0.049~ |
| | 210 | 20~ | 0.046~ |
| Titanium | 90 | 20~ | 0.061~ |
| Alloy | 110 | 20~ | 0.057~ |
| Aluminum | 65 | 20~ | 0.068~ |
| | 75 | 20~ | 0.065~ |
| Copper | 120 | 20~ | 0.056~ |
| Alloy | 140 | 20~ | 0.053~ |

FIG. 8 is a graph of the thickness T2 of the second plate 600 with respect to the modulus of the second plate 600, according to some embodiments.

Referring to FIG. 8, the range of the thickness T2 of the second plate 600 with respect to the modulus of the second plate 600, which makes the rigidity index of the second plate 600 to be greater than 20, as in Table 2, may be represented as a graph.

In FIG. 8, each of dots in circles may correspond to a minimum value of the range of the thickness T2 of the second plate 600 with respect to each modulus in Table 2. A trend line passing the dots in circles may be generated, and a corresponding curve Y3 may be represented as below.

Y3=8·10⁻⁷X2²−0.0004·X2+0.0874

where, X2 denotes a modulus (MPa) of a second plate.

As described above, the thickness T2 of the second plate 600 may have a value greater than Y2. In other words, Y3≤T3, and this may be represented as Equation 3 below.

8·10⁻⁷X2²−0.0004·X2+0.0874≤T2 Equation 3

where, T2 denotes a thickness (mm) of a second plate and X2 denotes a modulus (MPa) of the second plate.

As such, the thickness T1 of the first plate 500 and the thickness T2 of the second plate 600 are determined to have the rigidity indexes of the above ranges, and thus a thickness suitable to properties and/or modulus of each plate may be determined. Accordingly, the first plate 500 may have a suitable thickness for the display device 1 and/or the display panel 10 to realize a dumbbell shape when folded. Also, the first plate 500 may have a thickness of rigidity enough to protect the display panel 10. The second plate 600 may have a thickness for reinforcing the rigidity of the first plate 500 and preventing or reducing visibility of the flexure of components arranged below.

Referring back to FIGS. 5 and 6, the second plate 600 may be adhered to the first plate 500 by the adhesive member AD. According to some embodiments, the second plate 600 may be arranged to overlap the non-folding areas NFA and may not be arranged in the folding area FA. According to some embodiments, the sag preventing member 700 may be arranged below the first plate 500, in the folding area FA.

According to some embodiments, the first plate 500 may include stainless steel and the second plate 600 may include at least one of aluminum alloy or copper alloy. According to some embodiments, the first plate 500 may include fiber reinforced plastic, in particular, carbon fiber reinforced plastic, and the second plate 600 may include stainless steel. According to some embodiments, the first plate 500 may include fiber reinforced plastic, in particular, glass fiber reinforced plastic, and the second plate 600 may include stainless steel. However, materials are only examples, and the first plate 500 and the second plate 600 may each include various materials.

According to some embodiments, the second plate 600 and the sag preventing member 700 may be arranged on a same layer. According to some embodiments, the second plate 600 may include a (2-1)th plate 610 arranged at one side and a (2-2)th plate 620 arranged at the other side, based on the folding axis FAX. The (2-1)th plate 610 and the (2-2)th plate 620 may be spaced apart from each other based on the folding axis FAX. According to some embodiments, the (2-1)th plate 610 may overlap the first non-folding area NFA1. The (2-2)th plate 620 may overlap the second non-folding area NFA2.

The sag preventing member 700 may be provided between the (2-1)th plate 610 and the (2-2)th plate 620. According to some embodiments, the sag preventing member 700 may overlap the extension area EX and the curvature area CV. The sag preventing member 700 may be spaced apart from each of the (2-1)th plate 610 and the (2-2)th plate 620 in a direction towards the folding axis FAX. In other words, the sag preventing member 700 may be spaced apart from the second plate 600 by a length of the inflection area IA in the first direction. As such, the second plate 600 and the sag preventing member 700 are spaced apart from each other with the inflection area IA therebetween, and thus the display device 1 may be easily bent in reverse curvature in the inflection area IA.

The flat plate 810 may be arranged below the second plate 600. The flat plate 810 may include a first flat plate 811 located below the (2-1)th plate 610 and a second flat plate 812 located below the (2-2)th plate 620. The wing plate 820 may be arranged below the sag preventing member 700. The wing plate 820 may also include a first wing plate 821 arranged at one side and a second wing plate 822 arranged at the other side, based on the folding axis FAX.

The flat plate 810 and the wing plate 820 may be spaced apart from each other in the first direction. For example, the first flat plate 811 and the first wing plate 821 may be spaced apart from each other in the first direction by a length of the first inflection area IA1 in the first direction. The second flat plate 812 and the second wing plate 822 may be spaced apart from each other in the first direction by a length of the second inflection area IA2 in the first direction.

Also, the wing plates 820 may be spaced apart from each other in the first direction based on the folding axis FAX. In other words, the first wing plate 821 and the second wing plate 822 may be spaced apart from each other in the first direction based on the folding axis FAX.

Meanwhile, the sag preventing member 700 may be provided in any one of various combinations. According to some embodiments, the sag preventing member 700 may include a cushion member 710 and a film member 720. The cushion members 710 may be spaced apart from each other in the first direction based on the folding axis FAX. In other words, the cushion member 710 may include a first cushion member 711 at one side and a second cushion member 712 at the other side, based on the folding axis FAX. According to some embodiments, the cushion member 710 may overlap the extension area EX. In other words, the first cushion member 711 may overlap the first extension area EX1 and the second cushion member 712 may overlap the second extension area EX2.

The film member 720 may be provided between the first cushion member 711 and the second cushion member 712. The film members 720 may be spaced apart from each other in the first direction based on the folding axis FAX. In other words, the film member 720 may include a first film member 721 at one side and a second film member 722 at the other side, based on the folding axis FAX. According to some embodiments, the film member 720, for example, the first film member 721 and the second film member 722 may overlap the curvature area CV.

However, this is only an example, and a configuration of the sag preventing member 700 is not limited thereto and the sag preventing member 700 may include a metal layer such as copper alloy. Alternatively, only the cushion member 710 may be arranged and the film member 720 may be omitted. Alternatively, according to some embodiments, the cushion member 710 and the film member 720 are arranged horizontally in parallel to each other, but according to some embodiments, the sag preventing member 700 may be provided in any one of various combinations, for example, the cushion member 710 and the film member 720 may be arranged vertically in parallel to each other.

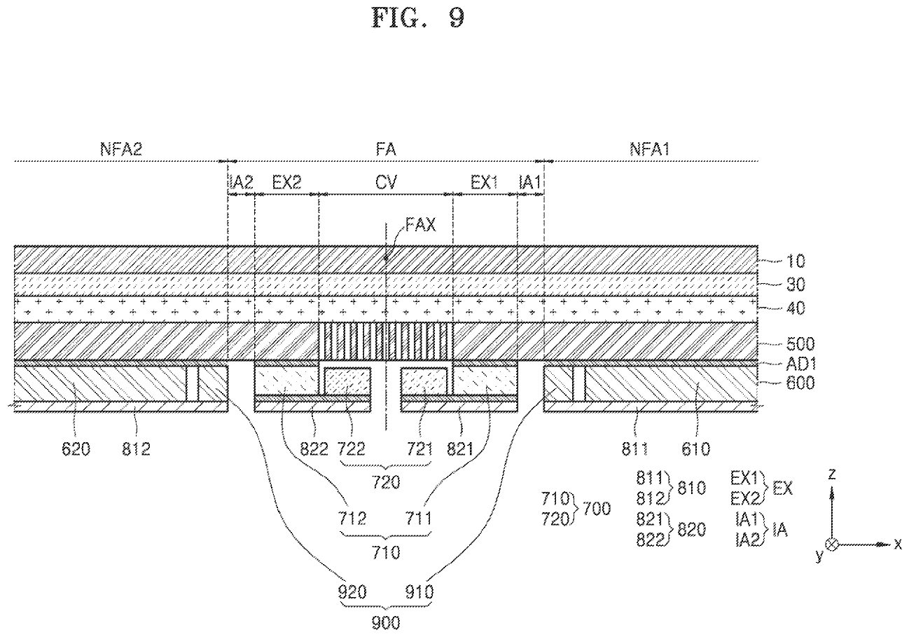

FIG. 9 is a cross-sectional view of the display device 1 according to some embodiments. The display device 1 shown in FIG. 9 is similar to the display device 1 described above, and thus only differences will be mainly described below.

Referring to FIG. 9, the display device 1 may further include a buffer member 900 provided between the second plate 600 and the sag preventing member 700. According to some embodiments, the buffer member 900 may include a first buffer member 910 arranged between the (2-1)th plate 610 and the first cushion member 711, and a second buffer member 920 arranged between the (2-2)th plate 620 and the second cushion member 712.

The first buffer member 910 may overlap a portion of the first non-folding area NFA1, in particular, a region connected from the first inflection area IA1 to the first non-folding area NFA1. According to some embodiments, the first buffer member 910 and the (2-1)th plate 610 may be supported by the first flat plate 811. The second buffer member 920 may overlap a portion of the second non-folding area NFA2, in particular, a region connected from the second inflection area IA2 to the second non-folding area NFA2. According to some embodiments, the second buffer member 920 and the (2-2)th plate 620 may be supported by the second flat plate 812.

The buffer member 900 may include a different material from the second plate 600. For example, the second plate 600 may include a metal material and the buffer member 900 may include a cushion material.

When the buffer member 900 is provided, the display device 1 may smoothly bend at the inflection area IA and a boundary between the inflection area IA and the non-folding area NFA, during folding. According to some embodiments, rigidity of the display device 1 may not rapidly change in a region from the inflection area IA to the non-folding area NFA during folding, through the buffer member 900.

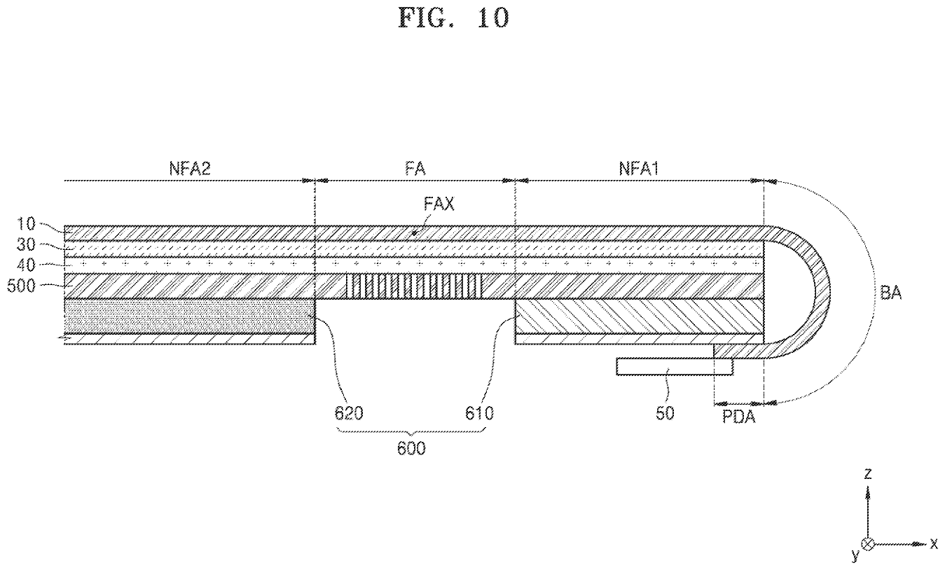

FIGS. 10 through 12 are cross-sectional views of the display device 1, according to some embodiments. The display device 1 shown in FIGS. 10 through 12 is similar to the display device 1 described above, and thus only differences will be mainly described below.

Referring to FIG. 10, the display panel 10 may include a bending area BA extending from one of the first non-folding area NFA1 and the second non-folding area NFA2, and a pad area PDA connected to the bending area BA. Hereinafter, for convenience of description, a case in which the bending area BA and the pad area PDA extend from the first non-folding area NFA1 will be mainly described.

The display panel 10 may bend in the bending area BA. In this case, at least portions of a bottom surface of the display panel 10 may face each other, and the pad area PDA of the display panel 10 may be located lower (the −z direction of FIG. 10) than other portions of the display panel 10. Accordingly, the area of a non-display area visible to a user may be reduced.

Driving units for applying a scan signal or data signal may be arranged in the pad area PDA. For example, a display driving unit may be arranged in the pad area PDA, wherein the display driving unit may receive control signals and power voltages, and generate and output signals and voltages for driving the display panel 10. The display driving unit may include an integrated circuit.

A display circuit board 50 may be electrically connected to the display panel 10. For example, the display circuit board 50 may contact and be connected to the pad area PDA of the display panel 10 or may be electrically connected to the pad area PDA through an anisotropic conductive film.

The display circuit board 50 may be a flexible printed circuit board (FPCB) that is bendable, or a rigid printed circuit board (PCB) that is rigid and thus is not easily bent. Alternatively, in some cases, the display circuit board 50 may be a complex printed circuit board including both the rigid PCB and the FPCB.

According to some embodiments, a touch sensor driving unit may be provided on the display circuit board 50. The touch sensor driving unit may include an integrated circuit. The touch sensor driving unit may be adhered on the display circuit board 50. The touch sensor driving unit may be electrically connected to sensor electrodes of the touch sensor layer of the display panel 10 through the display circuit board 50.

In addition, a power supply unit may be additionally provided on the display circuit board 50. The power supply unit may supply a driving voltage for driving pixels of the display panel 10 and the display driving unit.

The display circuit board 50 may be arranged below the second plate 600, in particular, the (2-1)th plate 610. The display circuit board 50 may overlap a portion of the (2-1)th plate 610. According to some embodiments, the (2-1)th plate 610 may have a thickness according to Equation 3 above. Accordingly, a flexure that may be generated in the display panel 10 due to the display circuit board 50 and the driving units arranged in the display circuit board 50 may not be visible to the user by the (2-1)th plate 610.

According to some embodiments, the (2-1)th plate 610 and the (2-2)th plate 620 may include a same material as in FIG. 5. According to some embodiments, the (2-1)th plate 610 and the (2-2)th plate 620 may include different materials as in FIG. 10. According to some embodiments, the (2-1)th plate 610 overlapping the display circuit board 50 may include at least one of stainless steel, titanium alloy, aluminum, or copper alloy. The (2-2)th plate 620 that does not overlap the display circuit board 50 may include a cushion material. Also, a modulus of the (2-2)th plate 620 may be smaller than a modulus of the (2-1)th plate 610.

According to some embodiments, the (2-1)th plate 610 and the (2-2)th plate 620 may have a same thickness. In other words, the (2-1)th plate 610 and the (2-2)th plate 620 may have a thickness according to Equation 3 above. However, embodiments according to the present disclosure are not limited thereto, and the (2-1)th plate 610 overlapping the display circuit board 50 may have a thickness according to Equation 3 above, and the (2-2)th plate 620 that does not overlap the display circuit board 50 may have a different thickness from the (2-1)th plate 610.

As such, the (2-1)th plate 610 and the (2-2)th plate 620 include different materials, and thus the (2-1)th plate 610 may prevent or reduce visibility of the display circuit board 50 and the driving units therebelow, and the (2-2)th plate 620 that does not overlap the display circuit board 50 may include the cushion material for protecting the display panel 10.

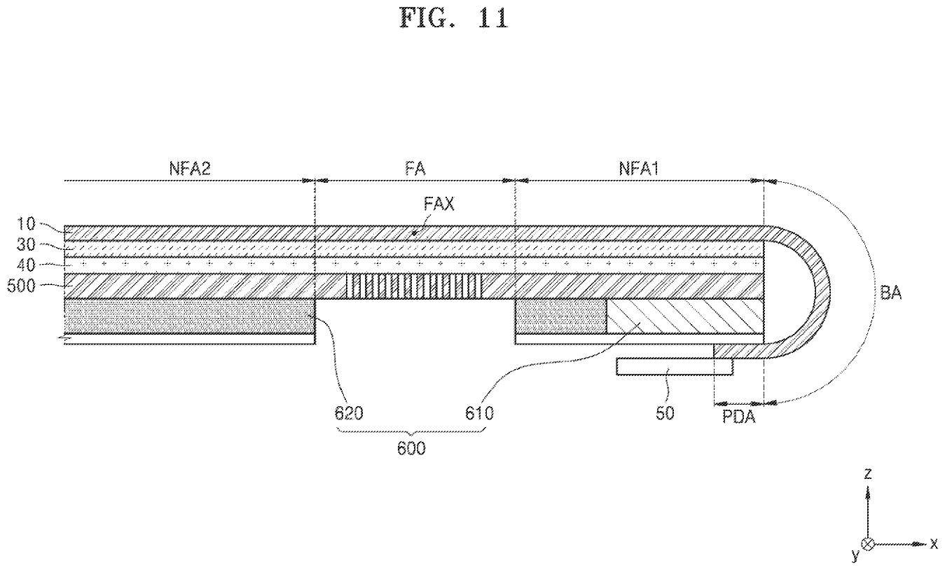

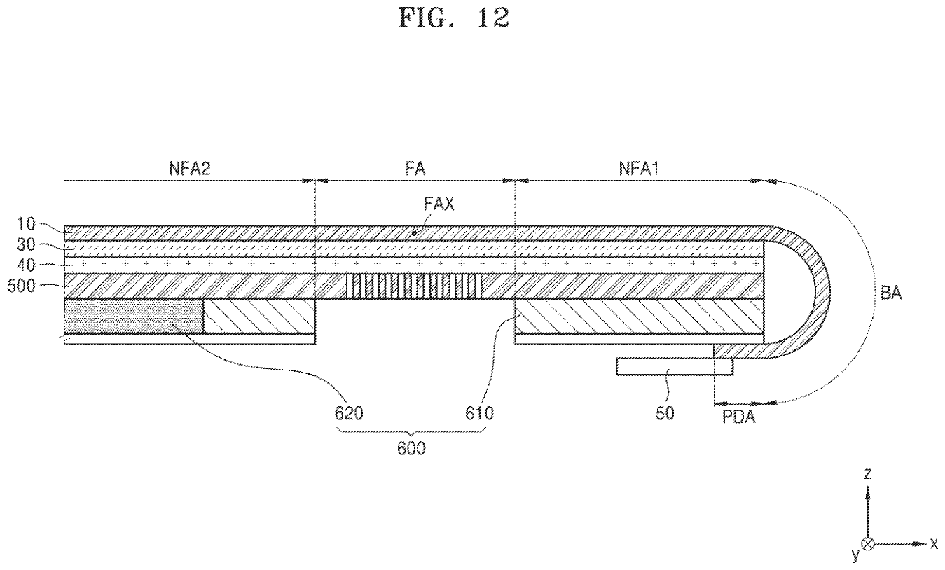

Referring to FIG. 11, according to some embodiments, a portion of the (2-1)th plate 610, which overlaps the display circuit board 50, and another portion of the (2-1)th plate 610, which does not overlap the display circuit board 50, may include different materials. For example, the portion of the (2-1)th plate 610, which overlaps the display circuit board 50, may include at least one of stainless steel, titanium alloy, aluminum, or copper alloy. The other portion of the (2-1)th plate 610, which does not overlap the display circuit board 50, may include the cushion material. According to some embodiments, the (2-2)th plate 620 may include a same material, for example, the cushion material, as the other portion of the (2-1)th plate 610, but embodiments according to the present disclosure are not limited thereto, and the (2-2)th plate 620 may include a third material that is different from the portion and the other portion of the (2-1)th plate 610.

Referring to FIG. 12, according to some embodiments, the (2-1)th plate 610 may include at least one of stainless steel, titanium alloy, aluminum, or copper alloy. According to some embodiments, a portion of the (2-2)th plate 620, which is adjacent to the folding area FA, may include a same material as the (2-1)th plate 610. The portion of the (2-2)th plate 620, which is adjacent to the folding area FA, may be, for example, a portion adjacent to the folding area FA, which corresponds to a half a length of the (2-2)th plate 620 in the first direction (for example, the x direction of FIG. 12). The other portion of the (2-2)th plate 620, which is distal from the folding area FA, may include a different material from the (2-1)th plate 610. For example, the other portion of the (2-2)th plate 620, which is distal from the folding area FA, may include the cushion material. Accordingly, portions of the second plate 600, which are adjacent to the folding area FA where the display device 1 is folded, may form uniform planes, and portions of the second plate 600, which are distal from the folding area FA and do not overlap the display circuit board 50, may include the cushion material to protect the display panel 10.

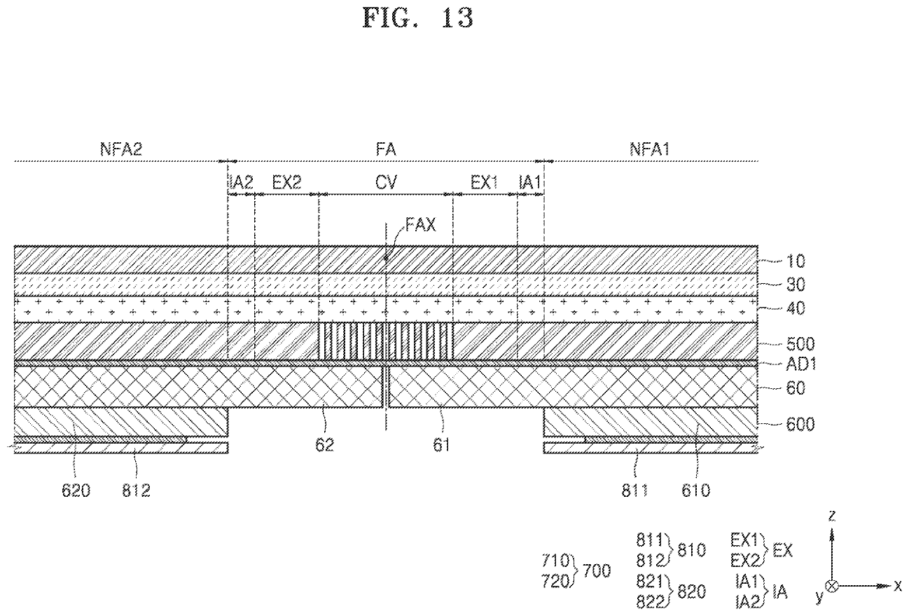

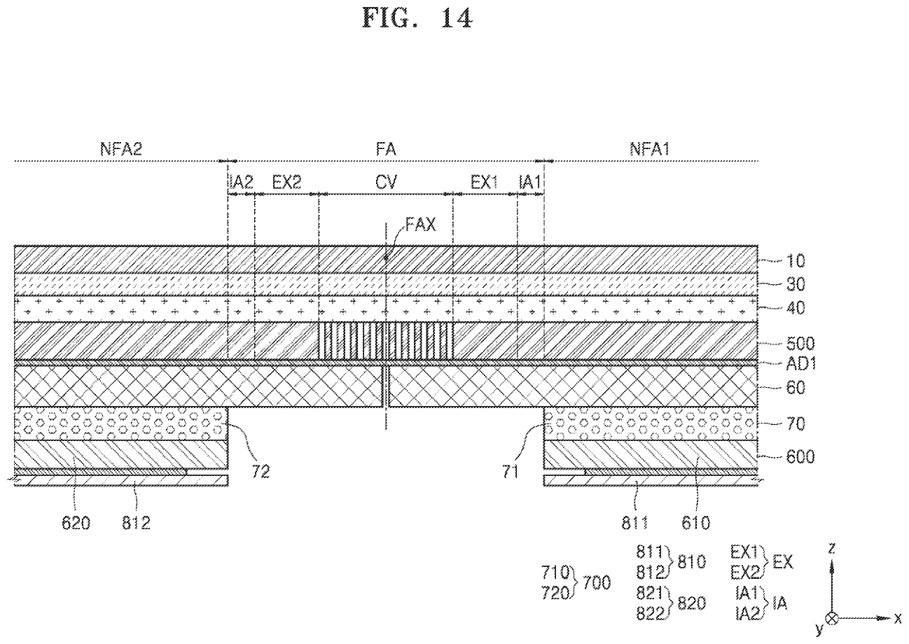

FIGS. 13 and 14 are cross-sectional views of the display device 1, according to some embodiments. The display device 1 shown in FIGS. 13 and 14 is similar to the display device 1 described above, and thus only differences will be mainly described below.

Referring to FIG. 13, according to some embodiments, a digitizer layer 60 may be provided between the first plate 500 and the second plate 600. The digitizer layer 60 may detect a signal input from an external electronic pen or the like. In particular, the digitizer layer 60 may detect strength, direction, and the like of the signal input from the electronic pen or the like.

The digitizer layer 60 may include a first digitizer layer 61 at one side and a second digitizer layer 62 at the other side, based on the folding axis FAX. The first digitizer layer 61 and the second digitizer layer 62 may be spaced apart from each other at a certain interval, based on the folding axis FAX. According to some embodiments, the first digitizer layer 61 may overlap a portion of the curvature area CV, the first extension area EX1, the first inflection area IA1, and the first non-folding area NFA1. According to some embodiments, the second digitizer layer 62 may overlap a portion of the curvature area CV, the second extension area EX2, the second inflection area IA2, and the second non-folding area NFA2.

Referring to FIG. 14, a buffer layer 70 may be further provided between the digitizer layer 60 and the second plate 600. The buffer layer 70 may include a first buffer layer 71 at one side and a second buffer layer 72 at the other side, based on the folding axis FAX. The first buffer layer 71 and the second buffer layer 72 may be spaced apart from each other at a certain interval, based on the folding axis FAX. According to some embodiments, the first buffer layer 71 may overlap the first non-folding area NFA1. According to some embodiments, the second buffer layer 72 may overlap the second non-folding area NFA2.

According to some embodiments, a display panel may have a further uniform surface in a folding area and various areas.

The characteristics of embodiments according to the present disclosure are not limited to those mentioned above, and other effects that are not mentioned may be clearly understood by one of ordinary skill in the art from the scope of claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a display panel comprising:
a folding axis: and
a folding area and non-folding areas on both sides of the folding axis, the display panel being configured to be folded along the folding axis, the folding area including a curvature area, inflection areas on both sides of the curvature area, and an extension area between the curvature area and the inflection areas; and
a first plate below the display panel,
wherein the first plate includes a lattice structure overlapping the curvature area, and is formed as a continuous plane throughout the extension area, the inflection areas, and the non-folding areas.

2. The display device of claim 1, wherein a rigidity index is defined by Equation 1, and a rigidity index of the first plate is between 40 and 400,
S=T³·X·1000 Equation 1
where S denotes a rigidity index, T denotes a thickness of a plate in mm, and X denotes a modulus of a plate in MPa.

3. The display device of claim 1, wherein a thickness of the first plate is in a range according to Equation 2,
2·10⁻⁶X1²−0.0009·X1+0.1364≤T1≤4·10⁻⁶X1²−0.0014·X1+0.2068 Equation 2
where T1 denotes a thickness of the first plate in mm and X1 denotes a modulus of the first plate in MPa.

4. The display device of claim 1, further comprising a second plate below the first plate,
wherein the second plate overlaps at least a portion of the non-folding areas.

5. The display device of claim 4, wherein the second plate is not in the folding area.

6. The display device of claim 4, wherein a rigidity index is defined by Equation 1, and a rigidity index of the second plate is greater than 20,
S=T³·X·1000 Equation 1
where S denotes a rigidity index, T denotes a thickness of a plate in mm, and X denotes a modulus of a plate in MPa.

7. The display device of claim 4, wherein a thickness of the second plate is in a range according to Equation 3,
8·c10⁻⁷X2²−0.0004·X2+0.0874≤T2 Equation 3
where T2 denotes a thickness of the second plate in mm and X2 denotes a modulus of the second plate in MPa.

8. The display device of claim 4, wherein the first plate includes stainless steel and the second plate includes a copper alloy.

9. The display device of claim 4, wherein the first plate includes fiber reinforced plastic and the second plate includes stainless steel.

10. The display device of claim 4, wherein the non-folding areas include a first non-folding area at a first side of the folding axis and a second non-folding area at a second side of the folding area,
the second plate includes a (2-1)th plate overlapping the first non-folding area and a (2-2)th plate overlapping the second non-folding area, and
the display device further comprises a display circuit board overlapping the first non-folding area and the (2-1)th plate and below the (2-1)th plate.

11. The display device of claim 10, wherein the (2-1)th plate and the (2-2)th plate include different materials.

12. The display device of claim 11, wherein a modulus of the (2-2)th plate is smaller than a modulus of the (2-1)th plate.

13. The display device of claim 10, wherein a portion of the (2-1)th plate, which overlaps the display circuit board, and another portion of the (2-1)th plate, which does not overlap the display circuit board, include different materials.

14. A display device comprising:
a display panel comprising:
a folding axis; and
a folding area and non-folding areas on both sides of the folding axis, the display panel being configured to be folded along the folding axis, the folding area including a curvature area, inflection areas on both sides of the curvature area, and an extension area between the curvature area and the inflection areas;
a first plate below the display panel; and
a digitizer layer below the first plate,
wherein the first plate includes a lattice structure overlapping the curvature area, and is formed as a continuous plane throughout the extension area, the inflection areas, and the non-folding areas.

15. The display device of claim 14, wherein a rigidity index is defined by Equation 1, and a rigidity index of the first plate is between 40 and 400,
S=T³·X·1000 Equation 1
where S denotes a rigidity index, T denotes a thickness of a plate in mm, and X denotes a modulus of a plate in MPa.

16. The display device of claim 14, wherein a thickness of the first plate is in a range according to Equation 2,
2·10⁻⁶X1²−0.0009·X1+0.1364≤T1≤4·10⁻⁶X1²−0.0014·X1+0.2068 Equation 2
where T1 denotes a thickness of the first plate in mm and X1 denotes a modulus of the first plate in MPa.

17. The display device of claim 14, further comprising a second plate below the digitizer layer,
wherein the second plate overlaps at least a portion of the non-folding areas.

18. The display device of claim 17, wherein a rigidity index is defined by Equation 1, and a rigidity index of the second plate is greater than 20,
S=T³·X·1000 Equation 1
where S denotes a rigidity index, T denotes a thickness of a plate in mm, and X denotes a modulus of a plate in MPa.

19. The display device of claim 17, wherein a thickness of the second plate is in a range according to Equation 3,
8·10⁻⁷X2²−0.0004·X2+0.0874≤T2 Equation 3
where T2 denotes a thickness of the second plate in mm and X2 denotes a modulus of the second plate in MPa.

20. The display device of claim 17, further comprising a buffer layer between the digitizer layer and the second plate.
